(19) United States
(12) Patent Application Publication
(10) Pub. No.: US 2011/0316391 A1
(43) Pub. Date: Dec. 29, 2011

(54) TUNING-FORK-TYPE PIEZOELECTRIC VIBRATING PLATE AND PIEZOELECTRIC DEVICE

(75) Inventors: HIDERYO MATSUDO, SAITAMA (JP); SHINGO KAWANISHI, SAITAMA (JP)

(73) Assignee: NIHON DEMPA KOGYO CO., LTD., TOKYO (JP)

(21) Appl. No.: 13/169,007

(22) Filed: Jun. 26, 2011

(30) Foreign Application Priority Data
Jun. 28, 2010 (JP) 2010-146298

(51) Int. Cl. H01L 41/053; H01L 41/04

(52) U.S. Cl. 310/344; 310/370

(57) ABSTRACT

A tuning-fork-type piezoelectric vibrating plate with a suppressed CI value and a piezoelectric device using thereof are provided. The tuning-fork-type piezoelectric vibrating plate includes: a base section formed by a piezoelectric material; and a pair of vibrating arms extended from the base section along a predetermined direction. On a front surface and a back surface of the vibrating arms, a first excitation groove is formed at the base section side, a second excitation groove is formed at a tip side of the vibrating arms, and a partition section is formed to separate the first excitation groove from the second excitation groove. A length from the base section side of the first excitation groove to the tip side of the second excitation groove in the predetermined direction is L1; a length of the first excitation groove in the predetermined direction is L2, and the ratio L2/L1 ranges from 0.51 to 0.65.

### CROSS-REFERENCE TO RELATED APPLICATION

This application claims the priority benefit of Japan application serial no. 2010-146298, filed Jun. 28, 2010. The entirety of the above-mentioned patent application is hereby incorporated by reference herein and made a part of this specification.

### BACKGROUND OF THE INVENTION

1. Field of the Invention

The invention relates to a tuning-fork-type piezoelectric vibrating plate having a pair of vibrating arms and a piezoelectric device having the tuning-fork-type piezoelectric vibrating plate in a cavity thereof.

2. Description of Related Art

Piezoelectric vibrating plates are being used as the signal source for the pace of wrist watches, etc. In recent years, piezoelectric vibrating plates are also used in portable electronic devices as a synchronization signal source. Among the piezoelectric vibrating plates, a tuning-fork-type piezoelectric vibrating plate is particularly adopted for generating accurate vibration and functioning with less electricity.

The tuning-fork-type piezoelectric vibrating plate includes a base section and a pair of vibrating arms extending from the base section in a predetermined direction. The vibrating arms have grooves and excitation electrodes thereon. Reference 1 (JP 2006-246449A) has disclosed a tuning-fork-type crystal vibrating plate. The groove in the vibrating arm of the tuning-fork-type crystal vibrating plate is divided into two grooves in its longitudinal direction, and the length of each groove can be adjusted to enhance the shock, while the CI (Crystal Impedance) value is maintained at a favorable value.

However, tuning-fork-type piezoelectric vibrating plates are required to provide a more stable vibration and have a lower CI value.

### SUMMARY OF THE INVENTION

In order to solve the aforementioned problem, the invention provides a tuning-fork-type piezoelectric vibrating plate and a piezoelectric device, wherein the ratio of the lengths of grooves in the vibrating arms are adjusted to suppress the CI value thereof.

In an embodiment, a tuning-fork-type piezoelectric vibrating plate includes a base section, which is formed by a piezoelectric material, and a pair of vibrating arms that extend from the base section in a predetermined direction. On a front surface and a back surface of the vibrating arms, a first excitation groove is formed at a base section side, a second excitation groove is formed at a tip side of the vibrating arm, and a partition section is formed to separate the first excitation groove from the second excitation groove. A length from the base section side of the first excitation groove to the tip side of the second excitation groove in the predetermined direction is L1; a length of the first excitation groove in the predetermined direction is L2; and the ratio L2/L1 is, for example, above 51%, 52%, preferably above 53%, or more preferably in a range of 54˜65%.

In one of the embodiments, a length of each of the vibrating arms in the predetermined direction is in a range of 1300˜1700 μm.

In another embodiment, the tuning-fork-type piezoelectric vibrating plate further includes a pair of supporting arms extending from the base section along the predetermined direction and outside of the pair of vibrating arms.

In another embodiment, the tuning-fork-type piezoelectric vibrating plate includes a frame body and a connection arm, wherein the frame body is formed to surround the supporting arms and the base section, and the connection arm is configured at a portion of a tip of the supporting arms to connect the pair of supporting arms with the frame body.

According to another embodiment, a piezoelectric device includes the aforementioned tuning-fork-type piezoelectric vibrating plate, a package with the tuning-fork-type piezoelectric vibrating plate disposed therein, and a lid sealing the package.

In yet another embodiment, the piezoelectric device includes the aforementioned tuning-fork-type piezoelectric vibrating plate, a base bonded to a back surface of the frame body, and a lid bonded to a front surface of the frame body, wherein the vibrating arms, the base section, the supporting arms, and the connection arm are sealed by the frame body, the base, and the lid.

According to the invention, a tuning-fork-type piezoelectric vibrating plate capable of suppressing the CI value and a piezoelectric device using the tuning-fork-type piezoelectric vibrating plate are provided.

To better convey the above features and advantages of the invention, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1(a) is a schematic perspective view of a piezoelectric device 100. FIG. 1(b) is a cross-sectional view of the piezoelectric device 100, and FIG. 1(c) illustrates a top view of a package 20 with a tuning-fork-type piezoelectric vibrating plate 30 disposed therein.

FIG. 2(a) is a schematic view of the tuning-fork-type piezoelectric vibrating plate 30, and FIG. 2(b) is a cross-sectional view along Line C-C of FIG. 2(a).

FIG. 3 provides a graph that shows the relationship between the ratio L2/L1 of the tuning-fork-type piezoelectric vibrating plate 30 and a CI value.

FIG. 4 is a schematic view of a tuning-fork-type piezoelectric vibrating plate 230.

FIG. 5(a) provides a schematic top view of a package 320 with a tuning-fork-type piezoelectric vibrating plate 330 disposed therein, FIG. 5(b) depicts a top view of the tuning-fork-type piezoelectric vibrating plate 330, and FIG. 5(c) is a cross-sectional view along Line D-D of FIG. 5(b).

FIG. 6(a) is a schematic perspective view of a piezoelectric device 400. FIG. 6(b) is an exploded cross-sectional view along Line E-E of FIG. 6(a).

FIG. 7(a) illustrates a schematic view of a tuning-fork-type piezoelectric vibrating plate 430, and FIG. 7(b) is a cross-sectional view along Line F-F of FIG. 7(a).

### DESCRIPTION OF EMBODIMENTS

### First Embodiment

<Piezoelectric device 100>

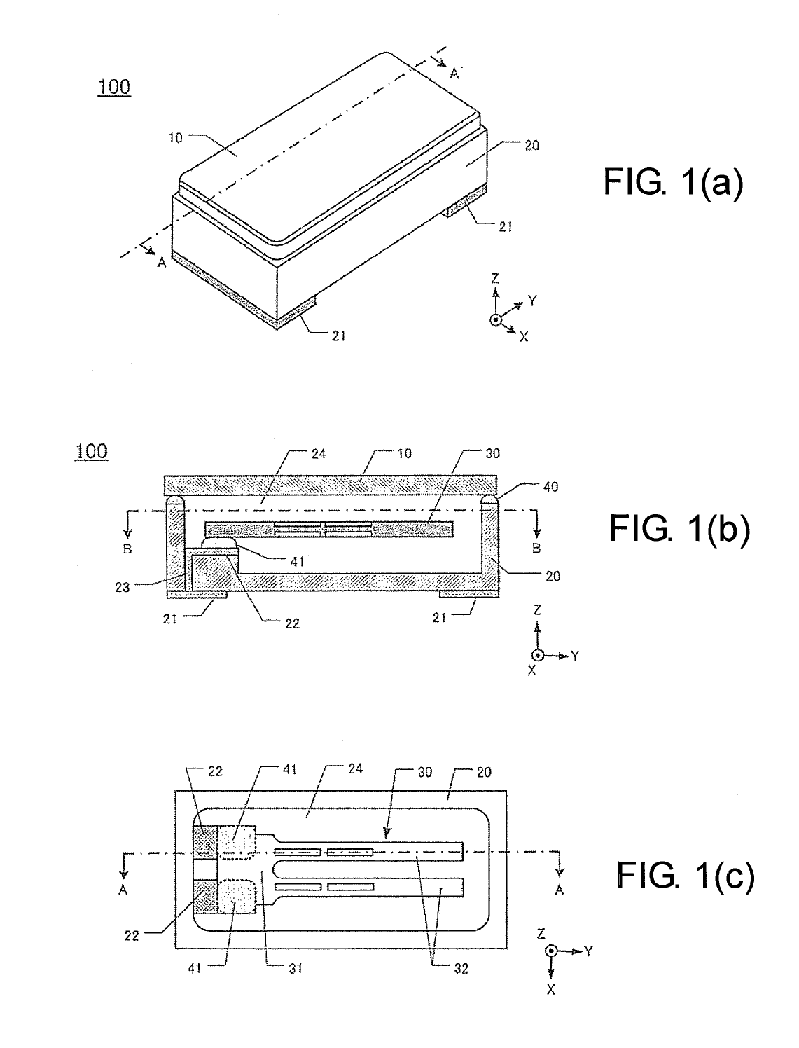

FIG. 1(a) is a schematic perspective view of a piezoelectric device 100. The piezoelectric device 100 includes a lid 10, a package 20, and a tuning-fork-type piezoelectric vibrating plate 30 disposed in the package 20 (see FIG. 1(b)). In the following descriptions, an extending direction of vibrating arms 32 (see FIG. 1(c)) of the tuning-fork-type piezoelectric vibrating plate 30, which is also a longitudinal direction of the package 20, is referred to as the Y-axis direction; a transverse direction of the package 20, along which the vibrating arms 32 are parallel to each other, is referred to as the X-axis direction; and a direction perpendicular to the X-axis direction and the Y-axis direction is referred to as the Z-axis direction.

A cavity 24 (see FIG. 1(b)) is formed in the package 20, and the tuning-fork-type piezoelectric vibrating plate 30 is disposed in the cavity 24. In addition, an external electrode 21 is disposed on a −Z axis surface of the package 20. The lid 10 is disposed on a +Z axis surface of the package 20 to seal the package 20.

FIG. 1(b) provides a cross-sectional view of the piezoelectric device 100 along Line A-A, as depicted in FIG. 1(a) and FIG. 1(c). The cavity 24 is formed inside the package 20, and a connection electrode 22 is formed in the cavity 24. The connection electrode 24 is electrically connected with the external electrode 21 via a conductor 23. Moreover, the tuning-fork-type piezoelectric vibrating plate 30 is positioned in the cavity 24 and connected with the connection electrode 22 via a conductive adhesive 41.

FIG. 1(c) illustrates a top view of the package 20 with the tuning-fork-type piezoelectric vibrating plate 30 disposed therein. FIG. 1(c) is a cross-sectional view along Line B-B of FIG. 1(b). The tuning-fork-type piezoelectric vibrating plate 30 has a base section 31 and a pair of vibrating arms 32 extending from the base section 31. Moreover, connection electrodes 22 are formed at two positions in the package 20, and the base section 31 of the tuning-fork-type piezoelectric vibrating plate 30 is connected with the connection electrodes 22.

<Tuning-Fork-Type Piezoelectric Vibrating Plate 30>

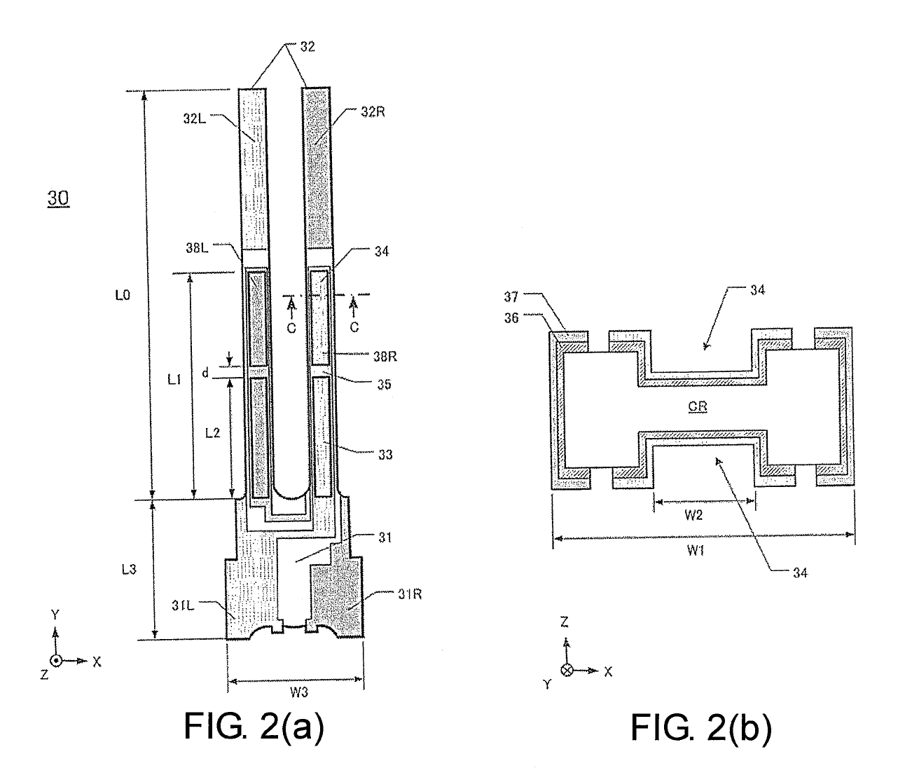

FIG. 2(a) illustrates the details of the tuning-fork-type piezoelectric vibrating plate 30, and FIG. 2(b) is a cross-sectional view along Line C-C of FIG. 2(a). The following descriptions of the tuning-fork-type piezoelectric vibrating plate 30 are provided with reference to FIG. 2(a) and FIG. 2(b).

The tuning-fork-type piezoelectric vibrating plate 30 includes the base section 31 and the pair of vibrating arms 32, which extend from the base section 31 and are in parallel to each other. Moreover, a base material of the tuning-fork-type piezoelectric vibrating plate 30 includes a piezoelectric material CR, and electrodes are formed on a surface of the piezoelectric material CR. Considering the difficulty of directly disposing electrodes formed of Au or Ag on the piezoelectric material CR, a first layer 36 having the same shape as the electrode is disposed on the surface of the piezoelectric material CR, and a second layer 37 is disposed on the first layer 36. The piezoelectric material CR comprises crystal, tantalic acid lithium, lithium niobate, or the like. A material of the first layer 36 comprises Cr, Ni, or other suitable materials. A material of the second layer 37 comprises Au, Ag, or other suitable materials.

A groove with a bottom is formed in each of the vibrating arms 32. Specifically, a first excitation groove 33 is formed in the vibrating arms 32 on the side of the base section 31, and a second excitation groove 34 is formed on the tip side of the vibrating arms 32. An end of the first excitation groove 33 on the side of the base section 31 is positioned at the boundary between the base section 31 and the vibrating arms 32. In addition, the first excitation groove 33 and the second excitation groove 34 are formed on a front surface (+Z axis surface) and a back surface (−Z axis surface) of the vibrating arms 32. The grooves in the vibrating arms 32 suppress the increase of the crystal impedance value (CI value). Further, a partition section 35 is formed between the first excitation groove 33 and the second excitation groove 34 to separate the first excitation groove 33 from the second excitation groove 34. The partition section 35 enhances the strength against the shock of the vibrating arms 32.

Two electrodes are formed on the tuning-fork-type piezoelectric vibrating plate 30, wherein the two electrodes are not electrically connected with each other and apply different voltages. One of the two electrodes is formed by an electrode 31R disposed on +X axis side of the base section 31; an electrode 32R disposed on an area outside the first excitation groove 33, the second excitation groove 34, and the partition section 35 on +X axis side of the vibrating arms 32; and an electrode 38L disposed on the first excitation groove 33, the second excitation groove 34, and the partition section 35 on −X axis side of the vibrating arms 32. The other of the two electrodes is formed by an electrode 31L disposed on −X axis side of the base section 31; an electrode 32L disposed on an area outside the first excitation groove 33, the second excitation groove 34, and the partition section 35 on −X axis side of the vibrating arms 32; and an electrode 38R disposed on the the first excitation groove 33, the second excitation groove 34, and the partition section 35 on +X axis side of the vibrating arms 32. In FIG. 2(a), electrodes of the same potential are marked with the same hatching.

FIG. 2(a) and FIG. 2(b) further provide the dimensions of each part of the tuning-fork-type piezoelectric vibrating plate 30. Referring to FIG. 2(a) and FIG. 2(b), a width W1 of the vibrating arm 32 in the X-axis direction is 100 μm; a width W2 of the groove is 70 μm; and a width W3 of the base section 31 is 500 μm. Moreover, a length d of the partition section 35 in the Y-axis direction is 15 μm; a length L0 of the vibrating arm 32 is 1650 μm; and a length L3 of the base section 31 is 600 μm.

<Experiment>

The CI value varies greatly according to the ratio of the lengths of the first excitation groove 33 and the second excitation groove 34. In the experiment, a total length that includes the first excitation groove 33, the second excitation groove 34, and the partition section 35 in the Y-axis direction is set to L1, and a length of the first excitation groove 33 in the Y-axis direction is set to L2. The CI value that respectively corresponds to each L2/L1 ratio is measured as below.

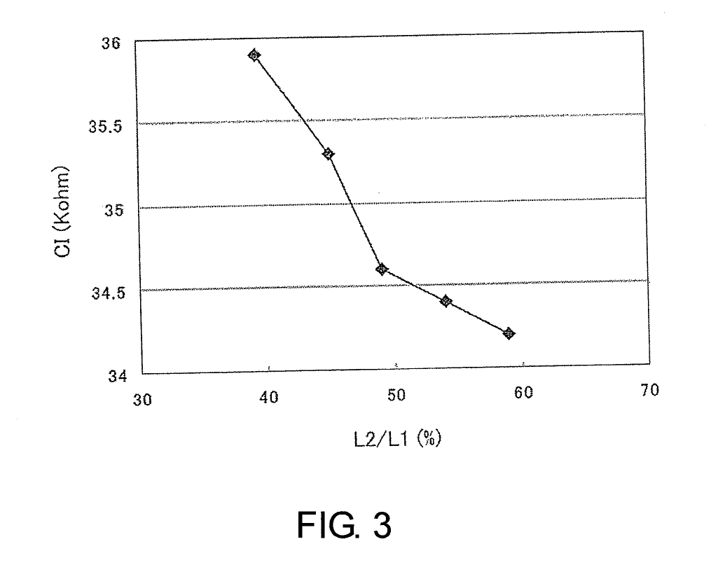

FIG. 3 is a graph showing a relationship between the L2/L1 ratio and the CI value of the tuning-fork-type piezoelectric vibrating plate 30. In addition, Table 1 provides data of the L1, L2, L2/L1, and CI values. Based on FIG. 3 and Table 1, the results of the experiment are explained as follows.

TABLE 1

| | No. 1 | No. 2 | No. 3 | No. 4 | No. 5 |
|---|---|---|---|---|---|
| L1 (μm) | 814.5 | 814.5 | 814.5 | 814.5 | 814.5 |
| L2 (μm) | 320.0 | 360.0 | 400.0 | 440.0 | 480.0 |
| L2/L1 (%) | 39.29 | 45.00 | 49.11 | 54.02 | 58.93 |
| CI (kohm) | 35.9 | 35.3 | 34.6 | 34.4 | 34.2 |

The experiment was carried out based on five conditions. The number of the samples in each of the conditions is 50. Moreover, the CI value in Table 1 represents an average of the 50 samples. In addition, in the experiment, d=15 μm, and d/L1≈0.0184. The conditions are respectively numbered as No. 1˜No. 5. Referring to the data of No. 1 for example, Table 1 shows that the CI value is 35.9 kohm when L1 is 814.5 μm, L2 is 320 μm, and L2/L1 is 39.29%. Further, FIG. 3 illustrates the relationship between the L2/L1 ratios and the CI values of Table 1. According to FIG. 3, as the L2/L1 ratio increases, the CI value becomes lower. In addition, compared with the condition that the first excitation groove 33 and the second excitation groove 34 have the same length in the Y-axis direction, the CI value is improved when the first excitation groove 33 is made longer than the second excitation groove 34 (that is, entering the range of condition No. 4 from condition No. 3). However, in conditions No. 3˜No. 5, the decrease of the CI value slows down as the L2/L1 ratio increases. Therefore, even though the L2/L1 ratio is raised above 58.93% in condition No. 5, the CI value thereof is not greatly reduced. According to the above, a favorable CI value is obtained when the L2/L1 ratio is larger than that of condition No. 3; alternatively speaking, the L2/L1 ratio is, for example, above 51%, 52%, preferably above 53%, or more preferably above 54%.

According to the knowledge of the inventors of the invention, as disclosed in Reference 1, the tuning-fork-type piezoelectric vibrating plate has satisfactory anti-shock property when the L2/L1 ratio ranges from 35% to 65%. In view of the experiment and Reference 1, it is known that the tuning-fork-type piezoelectric vibrating plate has favorable anti-shock property and CI value when the L2/L1 ratio is, for example, over 51%, 52%, preferably over 53%, or more preferably in a range of 54%˜65%.

### Second Embodiment

<Tuning-Fork-Type Piezoelectric Vibrating Plate 230>

In the tuning-fork-type piezoelectric vibrating plate 30, the end of the first excitation groove 33 on the side of the base section 31 is positioned at the boundary between the base section 31 and the vibrating arms 32. However, said end of the first excitation groove 33 is also extended into the base section. The following paragraphs describe a tuning-fork-type piezoelectric vibrating plate 230, wherein a part of the first excitation groove enters the base section.

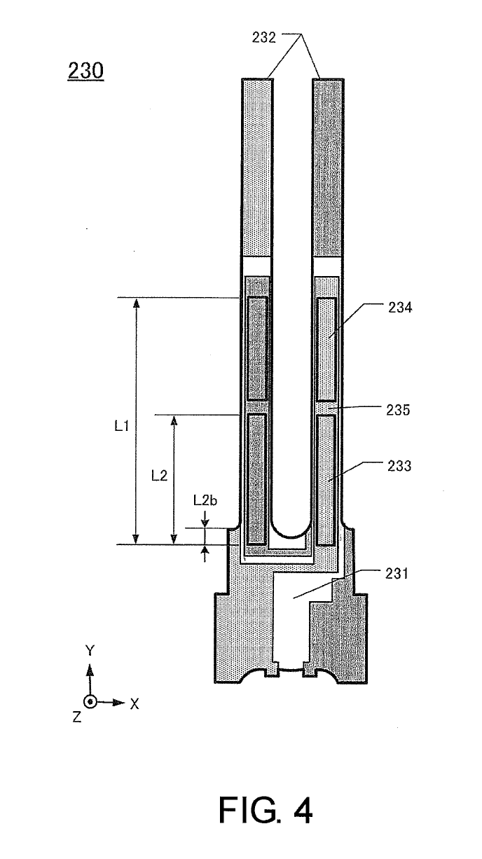

FIG. 4 illustrates the details of the tuning-fork-type piezoelectric vibrating plate 230. The tuning-fork-type piezoelectric vibrating plate 230 includes a base section 231 and a pair of vibrating arms 232. The tuning-fork-type piezoelectric vibrating plate 230 has the same shape and dimensions as the tuning-fork-type piezoelectric vibrating plate 30. Therefore, the following descriptions focus on the differences therebetween.

A groove with a bottom is formed in each of the vibrating arms 232 of the tuning-fork-type piezoelectric vibrating plate 230. Specifically, a first excitation groove 233 is formed in the vibrating arms 232 on the side of the base section 231, and a second excitation groove 234 is formed on the tip side of the vibrating arms 232. An end of the first excitation groove 233 is extended into the base section 231 for a distance L2b on −Y axis side. In addition, the first excitation groove 233 and the second excitation groove 234 are formed on a front surface (+Z axis surface) and a back surface (−Z axis surface) of the vibrating arms 232. A partition section 235 is disposed between the first excitation groove 233 and the second excitation groove 234 to separate the first excitation groove 233 from the second excitation groove 234.

A total length of the first excitation groove 233, the second excitation groove 234, and the partition section 235 in the Y-axis direction is set to L1, a length of the first excitation groove 233 in the Y-axis direction is set to L2, and L2b is about one-tenth the length of L2 (30 μm, for example). The same experiment results as shown in FIG. 3 are achievable by the foregoing tuning-fork-type piezoelectric vibrating plate. That is to say, when the ratio L2/L1 is for example above 51%, 52%, preferably above 53%, or more preferably between 54%˜65%, the tuning-fork-type piezoelectric vibrating plate has good anti-shock property and favorable CI value.

### Third Embodiment

<Tuning-Fork-Type Piezoelectric Vibrating Plate 330>

In another embodiment of the invention, a supporting arm is further disposed on the tuning-fork-type piezoelectric vibrating plate 30. The following paragraphs describe a tuning-fork-type piezoelectric vibrating plate 330 with a supporting arm.

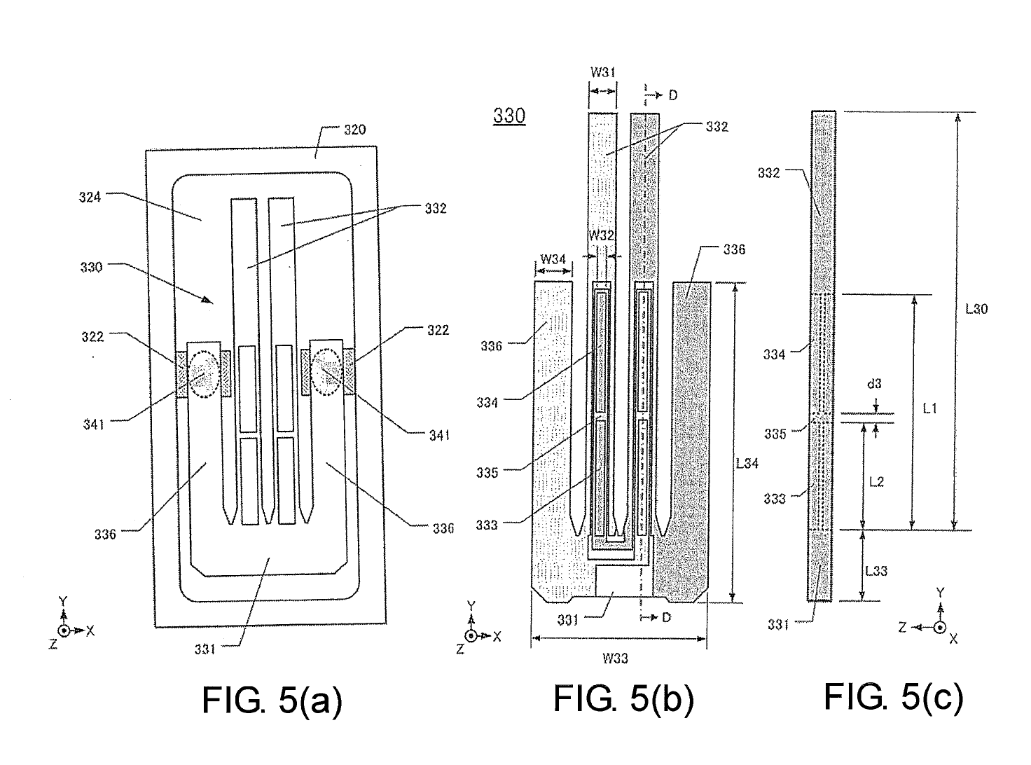

FIG. 5(a) is a schematic top view of a package 320 having the tuning-fork-type piezoelectric vibrating plate 330 therein. The tuning-fork-type piezoelectric vibrating plate 330 is disposed in the package 320, which constitutes a piezoelectric device (not shown) having the same shape as the piezoelectric device 100 of FIG. 1(a), and the tuning-fork-type piezoelectric vibrating plate 330 is sealed in the package 320 by a lid (not shown). A cavity 324 is formed inside the package 320, and two connection electrodes 322 are disposed in the cavity 324. The tuning-fork-type piezoelectric vibrating plate 330 includes a base section 331 and a pair of vibrating arms 332 extending from the base section 331. The tuning-fork-type piezoelectric vibrating plate 330 further includes a pair of supporting arms 336 that extend along the outside of the vibrating arms 332 and are in parallel to the vibrating arms 332. Tips of the supporting arms 336 are connected with the connection electrodes 322, so as to fix the tuning-fork-type piezoelectric vibrating plate 330 in the cavity 324. Because the tuning-fork-type piezoelectric vibrating plate 330 is supported by the pair of supporting arms 336, influence of the vibration released by the vibrating arms 332 and influence of temperature change and shock from outside the package 320 are reduced.

FIG. 5(b) further illustrates the tuning-fork-type piezoelectric vibrating plate 330 in detail. Specifically, the tuning-fork-type piezoelectric vibrating plate 330 comprises the base section 331, the vibrating arms 332 extending in parallel from the base section 331, and the supporting arms 336 extending along the outside of the vibrating arms 332 and in parallel to the vibrating arms 332.

A groove with a bottom is formed in each of the vibrating arms 332. More specifically, a first excitation groove 333 is formed in the vibrating arms 332 on the side of the base section 331, and a second excitation groove 334 is formed on the tip side of the vibrating arms 332. An end of the first excitation groove 333 on the side of the base section 331 is positioned at the boundary between the base section 331 and the vibrating arms 332. In addition, the first excitation groove 333 and the second excitation groove 334 are formed on the front surface (+Z axis surface) and the back surface (−Z axis surface) of the vibrating arms 332. Furthermore, a partition section 335 is formed between the first excitation groove 333 and the second excitation groove 334, so as to separate the first excitation groove 333 from the second excitation groove 334. The tuning-fork-type piezoelectric vibrating plate 330 further includes two electrodes that are not electrically connected with each other and respectively apply different voltages. A fabricating method of the electrodes is the same as that of the tuning-fork-type piezoelectric vibrating plate 30. In FIG. 5(b), electrodes of the same potential are indicated by the same hatching.

In regard to the dimensions of each part of the tuning-fork-type piezoelectric vibrating plate 330, a width W31 of the vibrating arm 332 in the X-axis direction is 100 μm; a width W32 of each of the grooves is 70 μm; a width W33, that includes the base section 331 and the supporting arms 336, is in a range of 600˜800 μm; and a width W34 of the supporting arms 336 is 100 μm. Further, a length L34 of each of the supporting arms 336 is 1200˜4500 μm.

FIG. 5(c) is a cross-sectional view along Line D-D of FIG. 5(b). In FIG. 5(c), the first excitation groove 333 and the second excitation groove 334 are represented by dotted lines. A length L30 of the vibrating arm 332 of the tuning-fork-type piezoelectric vibrating plate 330 is 1650 μm; and a length d3 of the partition section 335 in the Y-axis direction is 15 μm.

In this embodiment, a total length of the first excitation groove 333, the second excitation groove 334, and the partition section 335 in the Y-axis direction is set to L1, and a length of the first excitation groove 333 in the Y-axis direction is set to L2. In terms of the L2/L1 ratio, the same experiment results as shown in FIG. 3 are also achievable by tuning-fork-type piezoelectric vibrating plate 330 with the supporting arms 336. In other words, when the ratio L2/L1 is for example above 51%, 52%, preferably above 53%, or more preferably in a range of 54%˜65%, the tuning-fork-type piezoelectric vibrating plate having good anti-shock property and favorable CI value is provided.

### Fourth Embodiment

<Tuning-Fork-Type Piezoelectric Vibrating Plate 430>

In the tuning-fork-type piezoelectric vibrating plate 330, a frame body is also formed to surround the supporting arms 336 and the base section 331. The following paragraphs describe a tuning-fork-type piezoelectric vibrating plate 430 having a frame body and a piezoelectric device 400 equipped with the tuning-fork-type piezoelectric vibrating plate 430.

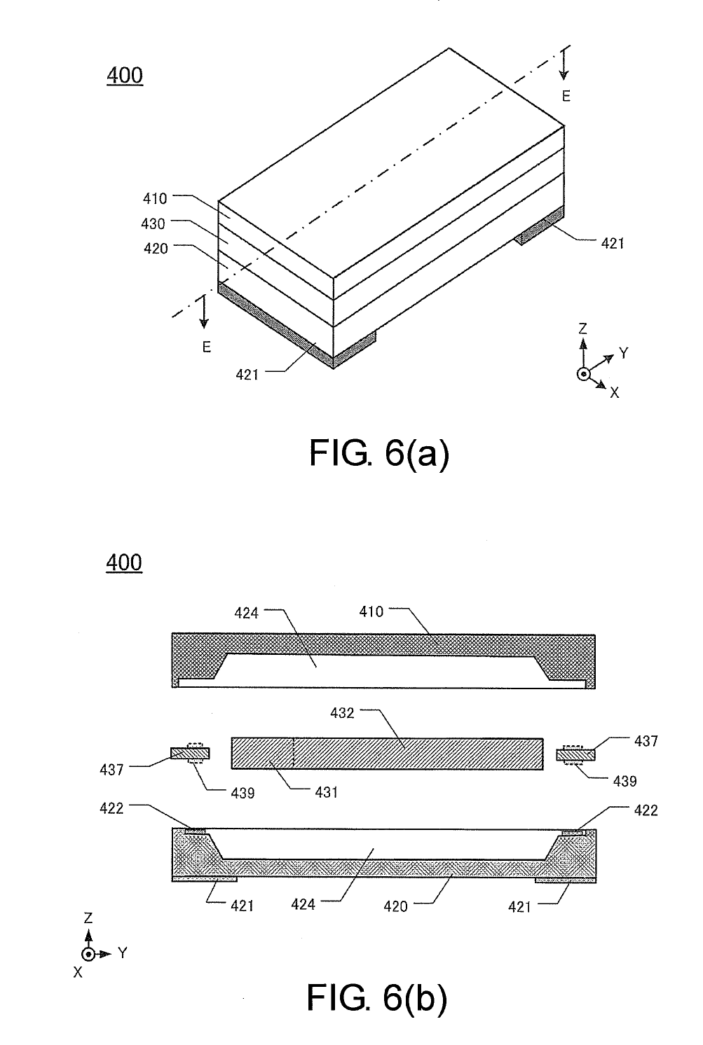

FIG. 6(a) is a schematic perspective view of the piezoelectric device 400. The piezoelectric device 400 is formed by disposing a lid 410 and a base 420 respectively on a top side and a bottom side of the tuning-fork-type piezoelectric vibrating plate 430. In addition, the base 420 includes an external electrode 421 formed on a bottom side thereof.

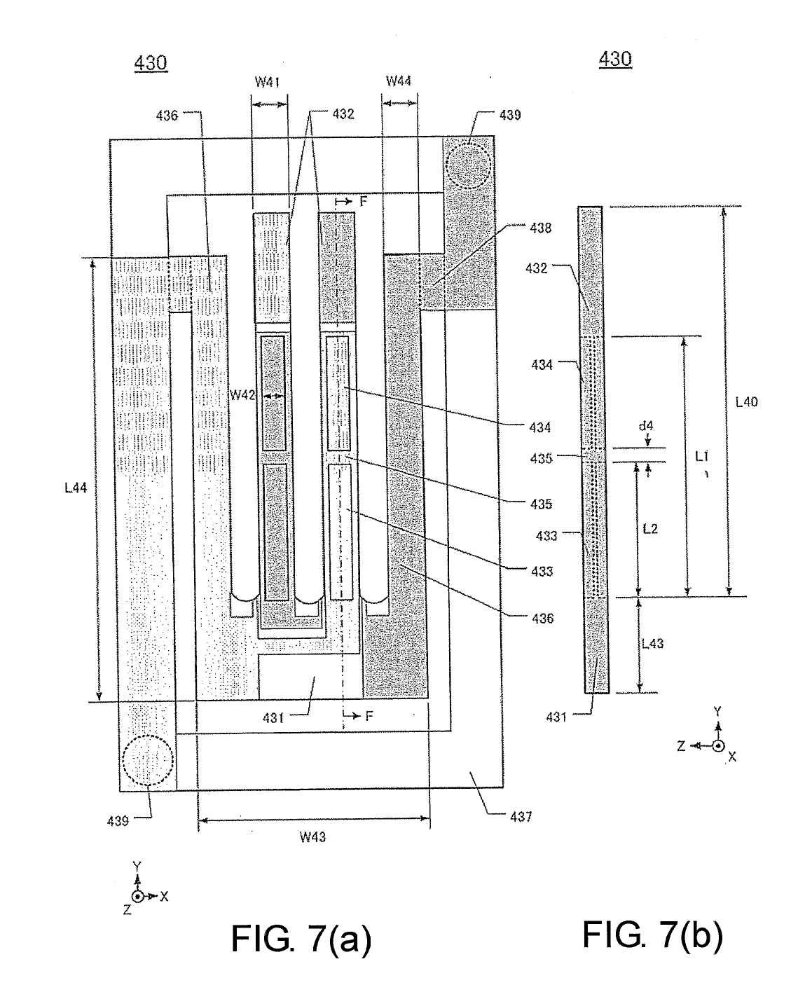

FIG. 6(b) provides an exploded view along Line E-E of FIG. 6(a). The tuning-fork-type piezoelectric vibrating plate 430 comprises a base section 431, vibrating arms 432, supporting arms 436 (with reference to FIG. 7(a)), connection arms 438 (with reference to FIG. 7(a)), and a frame body 437 that surrounds the foregoing elements. In the tuning-fork-type piezoelectric vibrating plate 430, the frame body 437 is sandwiched between the lid 410 and the base 420 and is supported by the lid 410 and the base 420. A concave is respectively formed on a surface of the lid 410 and a surface of the base 420, wherein said surfaces both face the tuning-fork-type piezoelectric vibrating plate 430. The concave is formed into a cavity 424 when the piezoelectric device 400 is fabricated. Except for the frame body 437, the elements of the tuning-fork-type piezoelectric vibrating plate 430 are disposed in the cavity 424. In addition, the connection electrodes 422 are formed on +Z axis surface of the base 420. The connection electrodes 422 are electrically connected with the external electrodes 421 by a conductor (not shown) that passes through the base 420. Furthermore, the connection electrodes 422 are electrically connected with an electrode junction 439 formed on the frame body 437 of the tuning-fork-type piezoelectric vibrating plate 430.

FIG. 7(a) illustrates details of the tuning-fork-type piezoelectric vibrating plate 430. Specifically, the tuning-fork-type piezoelectric vibrating plate 430 includes the base section 431, the vibrating arms 432 extending in parallel from the base section 431, and the supporting arms 436 that extend along the outside of the vibrating arms 432 and in parallel to the vibrating arms 432. The tuning-fork-type piezoelectric vibrating plate 430 further comprises the frame body 437 and the connection arms 438. The frame body 437 surrounds the base section 431, the vibrating arms 432, and the supporting arms 436. The connection arms 438 connect the supporting arms 436 and the frame body 437. A groove with a bottom is formed in each of the vibrating arms 432. A first excitation groove 433 is formed in the vibrating arms 432 on the side of the base section 431; and a second excitation groove 434 is formed on the tip side of the vibrating arms 432. An end of the first excitation groove 433, which is on the side of the base section 431, is positioned at the boundary between the base section 431 and the vibrating arms 432. Moreover, the first excitation groove 433 and the second excitation groove 434 are formed on a front surface (+Z axis surface) and a back surface (−Z axis surface) of the vibrating arms 432. In addition, a partition section 435 is formed between the first excitation groove 433 and the second excitation groove 434 to separate the first excitation groove 433 from the second excitation groove 434. The tuning-fork-type piezoelectric vibrating plate 430 also includes two electrodes that are not electrically connected with each other and apply different voltages. A fabricating method of the electrodes is the same as that of the tuning-fork-type piezoelectric vibrating plate 330. However, in the tuning-fork-type piezoelectric vibrating plate 430, the electrodes formed on the supporting arms are further extended into a corner of the frame body 437. The electrodes disposed on the tuning-fork-type piezoelectric vibrating plate 430 are electrically connected to the connection electrodes 422 of the base 420 by the electrode junctions 439 at corners of the frame body 437. In FIG. 7(a), electrodes of the same potential are indicated by the same hatching.

In regard to the dimensions of each part of the tuning-fork-type piezoelectric vibrating plate 430, a width W41 of each of the vibrating arms 432 in the X-axis direction is 100 μm; a width W42 of each of the grooves is 70 μm; a width W43, including the base section 431 and the supporting arms 436, is in a range of 600˜800 μm; and a width W44 of each of the supporting arms 436 is 100 μm. Moreover, a length L44 of the supporting arm 436 is in a range of 1200˜1500 μm.

FIG. 7(b) is a cross-sectional view along Line F-F of FIG. 7(a). In FIG. 7(b), the first excitation groove 433 and the second excitation groove 434 are indicated by dotted lines. A length L40 of the vibrating arm 432 is 1650 μm, and a length d of the partition section 435 in the Y-axis direction is 15 μm.

A total length of the first excitation groove 433, the second excitation groove 434, and the partition section 435 in the Y-axis direction is set to L1, and a length of the first excitation groove 433 in the Y-axis direction is set to L2. In terms of the ratio L2/L1, the same experiment results as shown in FIG. 3 are also achievable by the tuning-fork-type piezoelectric vibrating plate 430 with the frame body 437. When the ratio L2/L1 is for example above 51%, 52%, preferably above 53%, or more preferably in a range of 54%˜65%, the tuning-fork-type piezoelectric vibrating plate has good anti-shock property and favorable CI value.

Although the invention has been described with reference to the above exemplary embodiments, it is apparent to one of ordinary skill in the art that modifications to the described embodiments may be made without departing from the spirit of the invention.

For instance, the first excitation grooves of the tuning-fork-type piezoelectric vibrating plate 330 and the tuning-fork-type piezoelectric vibrating plate 430 are extended into the base sections thereof as the tuning-fork-type piezoelectric vibrating plate 230.

In the exemplary embodiments, the lengths L0, L30, and L40 of the vibrating arms are set to 1650 μm, the width W1 of the vibrating arm is set to 100 μm, and the width W2 of the groove is set to 70 μm. However, considering the interrelationship among W1, W2, L0, L30, and L40 (that is, interrelationship of vibration frequency), the width W2 and the lengths of the vibrating arms are made shorter if the width W1 is shortened. It should be noted that, if the width W1 of the arm is between 70˜110 μm, typically the length of the arm is adjustable in a range from 1300 μm to 1700 μm.

The length d of the partition section 35 in the Y-axis direction is set to 15 μm in the exemplary embodiment. However, the length d is also adjustable. According to the knowledge of the inventors of the invention, d/L1 is preferably in a range of 0.01˜0.018.

Accordingly, the scope of the invention is defined by the attached claims not by the above detailed descriptions.

What is claimed is:

1. A tuning-fork-type piezoelectric vibrating plate, comprising:
a base section, formed by a piezoelectric material; and
a pair of vibrating arms, extending from the base section in a predetermined direction,
wherein, on a front surface and a back surface of the vibrating arms, a first excitation groove is formed at a base section side, a second excitation groove is formed at a tip side of the vibrating arms, and a partition section is formed to separate the first excitation groove from the second excitation groove; and
wherein a length from the base section side of the first excitation groove to the tip side of the second excitation groove in the predetermined direction is L1, a length of the first excitation groove in the predetermined direction is L2, and a ratio L2/L1 ranges from 0.51 to 0.65.

2. The tuning-fork-type piezoelectric vibrating plate as claimed in claim 1, wherein a length of each of the vibrating arms in the predetermined direction is in a range of 1300˜1700 μm.

3. The tuning-fork-type piezoelectric vibrating plate as claimed in claim 1, further comprising:
a pair of supporting arms, extending from the base section along the predetermined direction and outside the pair of vibrating arms.

4. The tuning-fork-type piezoelectric vibrating plate as claimed in claim further comprising:
a pair of supporting arms, extending from the base section along the predetermined direction and outside the pair of vibrating arms.

5. The tuning-fork-type piezoelectric vibrating plate as claimed in claim 3, further comprising:
a frame body, formed to surround the pair of supporting arms and the base section; and
a connection arm, disposed on a portion of a tip of the supporting arms and connecting the pair of supporting arms with the frame body.

6. The tuning-fork-type piezoelectric vibrating plate as claimed in claim 4, further comprising:
a frame body, formed to surround the pair of supporting arms and the base section; and
a connection arm, disposed on a portion of a tip of the supporting arms and connecting the pair of supporting arms with the frame body.

7. A piezoelectric device, comprising:
the tuning-fork-type piezoelectric vibrating plate as claimed in claim 1;
a package with the tuning-fork-type piezoelectric vibrating plate disposed therein; and
a lid sealing the inside of the package.

8. A piezoelectric device, comprising:
the tuning-fork-type piezoelectric vibrating plate as claimed in claim 2;
a package with the tuning-fork-type piezoelectric vibrating plate disposed therein; and
a lid sealing the inside of the package.

9. A piezoelectric device, comprising:
the tuning-fork-type piezoelectric vibrating plate as claimed in claim 3;
a package with the tuning-fork-type piezoelectric vibrating plate disposed therein; and
a lid sealing the inside of the package.

10. A piezoelectric device, comprising:
the tuning-fork-type piezoelectric vibrating plate as claimed in claim 5;
a base bonded to a back surface of the frame body; and
a lid bonded to a front surface of the frame body;
wherein the pair of vibrating arms, the base section, the pair of supporting arms, and the connection arm are sealed by the frame body, the base, and the lid.

11. A piezoelectric device, comprising:
the tuning-fork-type piezoelectric vibrating plate as claimed in claim 6;
a base bonded to a back surface of the frame body; and
a lid bonded to a front surface of the frame body;
wherein the pair of vibrating arms, the base section, the pair of supporting arms, and the connection arm are sealed by the frame body, the base, and the lid.
